(19) United States
(12) Patent Application Publication
(10) Pub. No.: US 2021/0297058 A1
(43) Pub. Date: Sep. 23, 2021

(54) ACOUSTIC WAVE ELEMENT AND ACOUSTIC WAVE DEVICE

(71) Applicant: Murata Manufacturing Co., Ltd., Nagaokakyo-shi (JP)

(72) Inventor: Sunao YAMAZAKI, Nagaokakyo-shi (JP)

(21) Appl. No.: 17/342,676

(22) Filed: Jun. 9, 2021

Related U.S. Application Data
(63) Continuation of application No. PCT/JP2019/049696, filed on Dec. 18, 2019.

(30) Foreign Application Priority Data
Dec. 20, 2018 (JP) 2018-238063

(51) Int. Cl. H03H 9/10; H03H 9/02; H03H 9/05; H03H 9/25

(52) U.S. Cl. CPC H03H 9/1085; H03H 9/02559; H03H 9/25; H03H 9/059; H03H 9/02866

(57) ABSTRACT

An acoustic wave element includes a piezoelectric film, an interdigital transducer electrode on a first principal surface of the piezoelectric film, and a high acoustic velocity member near a second principal surface of the piezoelectric film. A surface of the high acoustic velocity member opposite to the piezoelectric film and a side surface of each of the high acoustic velocity member and the piezoelectric film are covered with resin. At least a portion of the side surface of the high acoustic velocity member is in contact with the resin. A gap is provided between the resin and at least a portion of the side surface of the piezoelectric film.

### CROSS REFERENCE TO RELATED APPLICATIONS

This application claims the benefit of priority to Japanese Patent Application No. 2018-238063 filed on Dec. 20, 2018 and is a Continuation Application of PCT Application No. PCT/JP2019/049696 filed on Dec. 18, 2019. The entire contents of each application are hereby incorporated herein by reference.

### BACKGROUND OF THE INVENTION

### 1. Field of the Invention

The present invention relates to an acoustic wave element including a multilayer film and to an acoustic wave device.

### 2. Description of the Related Art

In the related art, an acoustic wave device that includes an acoustic wave element including a multilayer film including a support substrate, a high acoustic velocity film, a low acoustic velocity film, a piezoelectric film, and other elements is used (for example, International Publication No. 2012/086639). According to the acoustic wave device disclosed in International Publication No. 2012/086639, the acoustic velocity of surface acoustic waves therein can be increased, and the frequency of them in the acoustic wave device can be higher.

When the acoustic wave device disclosed in International Publication No. 2012/086639 is sealed with resin for protection or other functions, however, if the resin is contracted or expanded by heat, a stress may occur in the piezoelectric film in response to an external force corresponding to the contraction or expansion of the resin, and the temperature coefficients of frequency (TCF) may deteriorate.

### SUMMARY OF THE INVENTION

Preferred embodiments of the present invention provide acoustic wave elements and acoustic wave devices that are each capable of reducing or preventing deterioration of the TCF caused by sealing with resin.

An acoustic wave element according to a preferred embodiment of the present invention includes a piezoelectric film, an interdigital transducer (IDT) electrode on a first principal surface of the piezoelectric film, and a high acoustic velocity member disposed near a second principal surface of the piezoelectric film. A surface of the high acoustic velocity member opposite to the piezoelectric film and a side surface of each of the high acoustic velocity member and the piezoelectric film are covered with resin. At least a section of the side surface of the high acoustic velocity member is in contact with the resin. A gap is provided between the resin and at least a section of the side surface of the piezoelectric film.

According to preferred embodiments of the present invention, the deterioration of the TCF caused by sealing with resin is able to be reduced or prevented.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1 is a cross-sectional view of an acoustic wave device according to a preferred embodiment of the present invention.

FIG. 2 is a cross-sectional view of an acoustic wave device according to a modification of a preferred embodiment of the present invention.

FIG. 3 illustrates a stress occurring in a piezoelectric film when a gap is not provided on a side surface of the piezoelectric film.

FIG. 4 illustrates a stress occurring in the piezoelectric film when the clearance is provided on the side surface of the piezoelectric film.

FIG. 5 illustrates a stress occurring in the piezoelectric film when resin is not provided.

### DETAILED DESCRIPTION OF THE PREFERRED EMBODIMENTS

Preferred embodiments of the present invention are described in detail below with reference to the drawings. The preferred embodiments described below indicate comprehensive or specific examples. The numeric values, shapes, materials, components, and arrangement and connection configurations of the components illustrated in the preferred embodiments below are examples and are not intended to limit the present invention. Among the components in the preferred embodiments below, components not described in the independent claims are described as optional components. The sizes or ratios of the sizes of the components illustrated in the drawings may not necessarily be precise. In the drawings, the same reference numerals denote the same or substantially the same configurations, and redundant description may be omitted or simplified.

In the present specification, the terms “upper” and “lower” do not indicate an upper direction (vertically upper) and a lower direction (vertically lower) in absolute spatial perception. The terms “upper” and “lower” are applicable to not only the case where two components are spaced apart from each other and another component is disposed between the two components, but also the case where two components are in close contact with each other and the two components are in contact with each other.

### PREFERRED EMBODIMENT

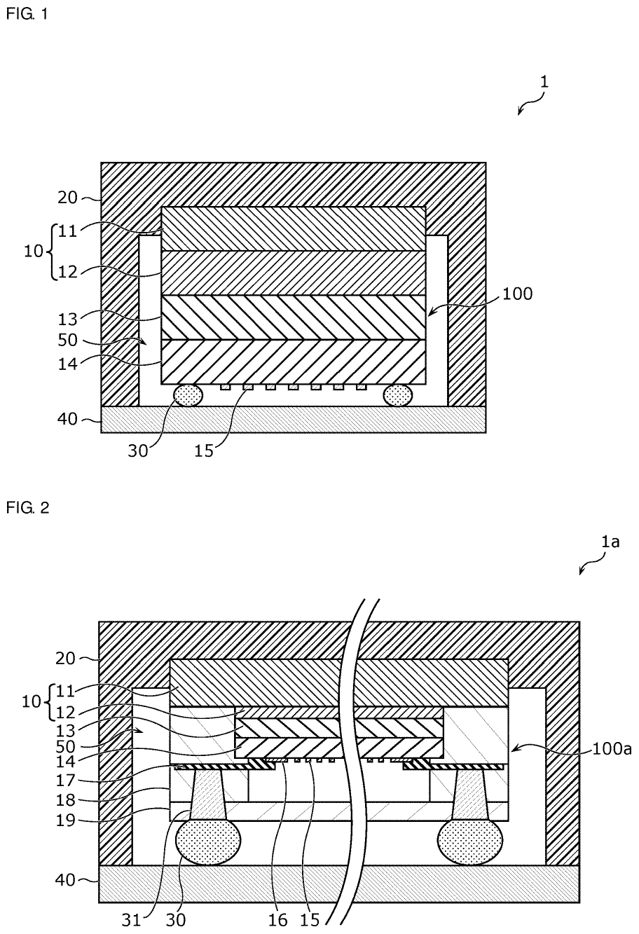

An acoustic wave device according to a preferred embodiment of the present invention is described below with reference to FIGS. 1 to 5.

### Configuration

FIG. 1 is a cross-sectional view of an acoustic wave device 1 according to a preferred embodiment of the present invention. An example of the acoustic wave device 1 may have a chip size package (CSP) structure.

As illustrated in FIG. 1, the acoustic wave device 1 includes a multilayer film including a high acoustic velocity member 10, a low acoustic velocity film 13, a piezoelectric film 14, and an IDT electrode 15 (hereinafter these elements are also referred to collectively as acoustic wave element 100), a resin 20, a bump 30, and a mounting substrate 40. The acoustic wave element 100 is mounted on a first principal surface of the mounting substrate 40. Specifically, the acoustic wave element 100 is mounted on the mounting substrate 40, which is lower, with the bump 30 disposed therebetween. The resin 20 is disposed on the first principal surface of the mounting substrate 40. Being near a first principal surface of the piezoelectric film 14 is also referred to as lower, and being near a second principal surface thereof is also referred to as upper.

The piezoelectric film 14 is made of, for example, a 50° Y-cut X-propagation lithium tantalate (LiTaO₃) piezoelectric single crystal or piezoelectric ceramic material (lithium tantalate single crystal or ceramic material cut at a plane whose normal line is an axis rotated about 50° from the Y axis about the X axis as its central axis and single crystal or ceramics in which a surface acoustic wave propagates in the X-axis direction). One example of the piezoelectric film 14 may have a thickness of about 600 nm. The material and cut-angles of the piezoelectric single crystal used as the piezoelectric film 14 are selected in accordance with desired specifications.

The IDT electrode 15 converts an acoustic wave propagating in the piezoelectric film 14 into an electric signal or converts an electric signal into an acoustic wave. The IDT electrode 15 is disposed on the first principal surface of the piezoelectric film 14, and one example of the IDT electrode 15 may be made of a metal selected among aluminum, copper, platinum, gold, titanium, nickel, chromium, silver, tungsten, molybdenum, tantalum, and other metals, or an alloy or a multilayer body made of two or more of these metals. One example of the IDT electrode 15 may have a thickness of about 157 nm. The IDT electrode 15 includes a pair of comb-shaped electrodes opposite to each other when the piezoelectric film 14 is viewed in plan view. Each of the comb-shaped electrodes of one pair includes a plurality of electrode fingers parallel or substantially parallel to each other and a busbar electrode (not illustrated) connecting the plurality of electrode fingers. The plurality of electrode fingers of one of the comb-shaped electrodes and the plurality of electrode fingers of the other comb-shaped electrode are interdigitated with each other along a direction perpendicular or substantially perpendicular to a propagation direction of a main-mode acoustic wave. Although not illustrated, the IDT electrode 15 is protected by being covered with a protective film. The protective film is a layer to adjust the frequency temperature characteristics, improve moisture resistance, and for other purposes, in addition to protecting the IDT electrode 15. One example of the protective film may be a dielectric film predominantly including silicon dioxide. One example of the thickness of the protective film may be about 20 nm.

The high acoustic velocity member 10 is disposed near (upper than) the second principal surface of the piezoelectric film 14 and includes a support substrate 11 and a high acoustic velocity film 12. The high acoustic velocity member 10 may not have a two-layer structure including the support substrate 11 and the high acoustic velocity film 12 and may be a single member including a high acoustic velocity support substrate defining and functioning as the support substrate 11 and the high acoustic velocity film 12.

The support substrate 11 supports the high acoustic velocity film 12, the low acoustic velocity film 13, the piezoelectric film 14, and the IDT electrode 15. Examples of the material used in the support substrate 11 may include piezoelectric materials, such as lithium tantalate, lithium niobate, and crystal, various ceramic materials, such as aluminum oxide, magnesium oxide, silicon nitride, aluminum nitride, silicon carbide, zirconium oxide, cordierite, mullite, steatite, and forsterite, dielectric materials, such as sapphire and glass, and semiconductors, such as silicon and gallium nitride. Here, one example of the support substrate 11 may be a silicon substrate with high heat dissipation.

The high acoustic velocity film 12 is provided between the support substrate 11 and the piezoelectric film 14 and is a layer in which the acoustic velocity of a bulk wave propagating therein is higher than the acoustic velocity of an acoustic wave propagating in the piezoelectric film 14. Examples of the material used in the high acoustic velocity film 12 may include various kinds of high acoustic velocity materials, such as aluminum nitride, aluminum oxide, silicon carbide, silicon nitride, silicon oxynitride, a diamond-like carbon (DLC) film, and diamond.

The low acoustic velocity film 13 is provided between the high acoustic velocity member 10 (specifically high acoustic velocity film 12) and the piezoelectric film 14 and is a layer in which the acoustic velocity of a bulk wave propagating therein is lower than the acoustic velocity of the bulk wave propagating in the piezoelectric film 14. Examples of the material used in the low acoustic velocity film 13 may include various materials, such as silicon dioxide, glass, silicon oxynitride, and tantalum oxide.

As described above, in the acoustic wave device 1, the IDT electrode 15, the piezoelectric film 14, the low acoustic velocity film 13, the high acoustic velocity film 12, and the support substrate 11 are disposed in this order in a direction from the mounting substrate 40 toward the upper side. Another component may be interposed between the piezoelectric film 14 and the low acoustic velocity film 13. Another component may be interposed between the low acoustic velocity film 13 and the high acoustic velocity film 12. Another component may be interposed between the high acoustic velocity film 12 and the support substrate 11.

The bump 30 is a ball-shaped electrode made of a metal having high conductivity and electrically connects the IDT electrode 15 and other elements to the mounting substrate 40. One example of the bump 30 may be a solder bump made of tin, silver, copper, and other metals. The bump 30 may include gold as its principal component.

The resin 20 covers the surface of the high acoustic velocity member 10 opposite to the piezoelectric film 14 (top surface) and the side surface of each of the high acoustic velocity member 10 and the piezoelectric film 14. The covering of the top surface and the side surface by the resin 20 means that another member may be disposed between the resin 20 and the top surface or the side surface. Here, at least a section of the side surface of the high acoustic velocity member 10 is in contact with the resin 20. One example of the resin 20 is in contact with the top surface of the support substrate 11, covers the top surface and is in contact with at least a section of the side surface of the support substrate 11. All of the side surface of the support substrate 11 may be in contact with the resin 20. One example of the resin 20 may be made of a resin, such as epoxy resin. The resin 20 may include thermosetting epoxy resin including an inorganic filler, such as silicon dioxide. Depending on the placement of the resin 20, reliability, including airtightness, thermal resistance, water resistance, moisture resistance, and insulation property, of the acoustic wave element 100 can be improved.

In the related art, as previously described, from the viewpoint of improving the reliability of the acoustic wave element 100, the high acoustic velocity member 10 is sealed with resin such that the resin 20 is in contact with all of the side surfaces of the acoustic wave element 100.

Because resin typically contracts or expands by heat, however, if the resin 20 is in contact with the acoustic wave element 100, the acoustic wave element 100 receives an external force from the resin 20 in response to the contraction or expansion of the resin 20. This produces a stress in the acoustic wave element 100, that is, a stress in the piezoelectric film 14, and thus the TCF deteriorates.

Therefore, a gap 50 is provided between the resin 20 and at least a section of the side surface of the piezoelectric film 14. The gap 50 being in contact with the resin 20 means that no other member is disposed between the gap 50 and the resin 20. As illustrated in FIG. 1, the gap 50 may be provided between the resin 20 and all of the side surface of the piezoelectric film 14. As illustrated in FIG. 1, in addition to being between the resin 20 and the side surface of the piezoelectric film 14, the gap 50 may be provided between the resin 20 and the side surface of the low acoustic velocity film 13, between the resin 20 and the side surface of the high acoustic velocity film 12, and between the resin 20 and the side surface of the support substrate 11. The gap 50, which is in contact with the side surface of the piezoelectric film 14 in FIG. 1, may not be in contact with it. That is, although no other member is provided between the gap 50 and the side surface of the piezoelectric film 14 in FIG. 1, another member may be provided therebetween. An aspect in which the gap 50 is not in contact with the side surface of the piezoelectric film 14 is described below with reference to FIG. 2.

The method for producing the gap 50 between the resin 20 and the side surface of the piezoelectric film 14 is not particularly limited. One example method may be covering the acoustic wave element 100 with a resin film such that a space is provided on the side surface of the acoustic wave element 100 including the side surface of the piezoelectric film 14 and sealing the acoustic wave element 100 covered with the resin film with resin while the space is maintained. In this way, the gap 50 can be provided on the side surface of the acoustic wave element 100. The resin 20 may include the resin film as a portion thereof, and the resin film may define the inner wall surface of the resin 20.

### Advantageous Effects

As described above, the acoustic wave element 100 includes the piezoelectric film 14, the IDT electrode 15 disposed on the first principal surface of the piezoelectric film 14, and the high acoustic velocity member 10 disposed near the second principal surface of the piezoelectric film 14. The surface of the high acoustic velocity member 10 opposite to the piezoelectric film 14 and the side surface of each of the high acoustic velocity member 10 and the piezoelectric film 14 are covered with the resin 20. At least a portion of the side surface of the high acoustic velocity member 10 is in contact with the resin 20, and the gap 50 is provided between the resin 20 and at least a portion of the side surface of the piezoelectric film 14.

In this configuration, in which the gap 50 is provided between the side surface of the piezoelectric film 14 and the resin 20, if the resin 20 contracts or expands, because the resin 20 and the piezoelectric film 14 are not in direct contact with each other, the piezoelectric film 14 is unlikely to receive an external force from the resin 20, a large stress is unlikely to occur, and deterioration of the TCF can be reduced or prevented. Because at least the portion of the side surface of the high acoustic velocity member 10 is in contact with the resin 20, heat can escape to the resin 20, and the heat dissipation can be improved.

The high acoustic velocity member 10 may include the support substrate 11 and the high acoustic velocity film 12 provided between the support substrate 11 and the piezoelectric film 14 and enable a bulk wave to propagate therein with an acoustic velocity higher than the acoustic velocity of an acoustic wave propagating in the piezoelectric film 14. At least the portion of the side surface of the support substrate 11 as the at least a portion of the side surface of the high acoustic velocity member 10 may be in contact with the resin 20.

In this configuration, the high acoustic velocity film 12 can enable surface acoustic waves to be confined in a portion where the piezoelectric film 14 and the low acoustic velocity film 13 are laminated and can prevent them from leaking to a region above the support substrate 11.

All of the side surface of the support substrate 11 may be in contact with the resin 20.

In this configuration, because as the portion where the resin 20 and the side surface of the support substrate 11 are in contact with each other increases, heat can more effectively escape to the resin 20, when all of the side surface of the support substrate 11 is in contact with the resin 20, the heat dissipation can be further improved.

The gap 50 may be provided between the resin 20 and all of the side surface of the piezoelectric film 14.

In this configuration, because as the portion where the piezoelectric film 14 and the resin 20 are not in contact with each other increases, the piezoelectric film 14 is more unlikely to receive an external force from the resin 20, when the gap 50 is provided between the resin 20 and all of the side surface of the piezoelectric film 14, the deterioration of the TCF can be further reduced or prevented.

The acoustic wave element 100 may further include the low acoustic velocity film 13 between the high acoustic velocity member 10 and the piezoelectric film 14 and enable a bulk wave to propagate therein with an acoustic velocity lower than the acoustic velocity of a bulk wave propagating in the piezoelectric film 14.

In this configuration, because of the structure and the characteristic in which the energy of acoustic waves intrinsically focuses on a medium with a low acoustic velocity, leakage of the energy of surface acoustic waves to outside the IDT electrode 15 can be reduced or prevented.

The gap 50 may be in contact with the side surface of the piezoelectric film 14.

In this configuration, a preferred embodiment of the present invention can be applied to an acoustic wave element 100 having the CSP structure.

The acoustic wave device 1 includes the acoustic wave element 100, the resin 20, and the mounting substrate 40. The acoustic wave element 100 is mounted on the first principal surface of the mounting substrate 40. The resin 20 is disposed on the first principal surface of the mounting substrate 40.

In this configuration, the acoustic wave device 1 capable of reducing or preventing the deterioration of the TCF caused by sealing with resin can be provided.

### Modification

Next, a case where another member is disposed between the gap 50 and the side surface of the piezoelectric film 14 is described with reference to FIG. 2.

FIG. 2 is a cross-sectional view of an acoustic wave device 1a according to a modification of a preferred embodiment of the present invention. One example of the acoustic wave device 1a may have a wafer level package (WLP) structure and can be more compact and thinner than the acoustic wave device 1. As for the acoustic wave device 1a, the same reference numerals denote the same or substantially the same configurations as those in the acoustic wave device 1 illustrated in FIG. 1, and the redundant description is omitted. In the acoustic wave device 1, as seen in plan view (top view), the size of the support substrate 11 is the same or substantially the same as the size of each of the low acoustic velocity film 13 and the piezoelectric film 14. In the acoustic wave device 1a, as seen in plan view (top view), the size of the support substrate 11 is larger than the size of each of the high acoustic velocity film 12, the low acoustic velocity film 13, and the piezoelectric film 14.

The acoustic wave device 1a includes an acoustic wave element 100a in place of the acoustic wave element 100. The acoustic wave element 100a includes, as components not described in the acoustic wave element 100, a terminal electrode 16, a wiring electrode 17, a support member 18, a cover layer 19, and a columnar electrode 31.

The support member 18 is provided between the support substrate 11 and the cover layer 19 and between the resin 20 and the side surface of each of the piezoelectric film 14, low acoustic velocity film 13, and the high acoustic velocity member 10. The gap 50 is provided between the support member 18 and the resin 20. That is, the support member 18 is disposed between the gap 50 and the side surface of the piezoelectric film 14. The support member 18 covers the side surface of each of the high acoustic velocity film 12, the low acoustic velocity film 13, and piezoelectric film 14 on a lower surface of the support substrate 11 and supports them. The material of the support member 18 is not particularly limited. One example of the support member 18 may be made of a material including at least one of polyimide, epoxy, benzocyclobutene (BCB), polybenzoxazole (PBO), a metal, and silicon oxide.

The cover layer 19 is lower than the support member 18 and is a layer defining a space that the IDT electrode 15 faces. The cover layer 19 is opposite to the principal surface of the piezoelectric film 14 where the IDT electrode 15 is disposed and is spaced away from the IDT electrode 15. Thus, as illustrated in FIG. 2, the space is provided between the IDT electrode 15 and the cover layer 19. The support member 18 and the cover layer 19 can seal the space between the IDT electrode 15 and the cover layer 19 in a liquid-tight manner. That is, entry of liquid, such as water, for example, into that space can be reduced or prevented. The material of the cover layer 19 is not particularly limited. One example of the cover layer 19 may be made of a material including at least one of polyimide, epoxy, BCB, PBO, silicon, silicon oxide, lithium tantalate (LiTaO₃), and lithium niobate (LiNbO₃).

The wiring electrode 17 is connected to the IDT electrode 15, is disposed around the IDT electrode 15, and may include a plurality of multilayer bodies made of metals or alloys, for example.

The IDT electrode 15 is electrically connected to the mounting substrate 40 with the terminal electrode 16, the wiring electrode 17, the columnar electrode 31, and the bump 30 disposed therebetween. In one example case, the wiring electrode 17 is embedded in the support member 18, and the columnar electrode 31 extends through the cover layer 19 and is embedded in the support member 18.

As described above, in the case where the support member is disposed between the gap 50 and the side surface of the piezoelectric film 14, because the support member 18 is not in direct contact with the resin 20, if the resin 20 contracts or expands, the support member 18 is unlikely to receive an external force from the resin 20. Accordingly, the piezoelectric film 14, which is in direct contact with the support member 18, is unlikely to receive an external force from the resin 20 through the support member 18, and the deterioration of the TCF can be reduced or prevented.

The gap 50 can be disposed similarly to the gap 50 in the acoustic wave element 100. In one example case, the support substrate 11 and the support member 18 are covered with a resin film such that a space is provided on the side surface of the support member 18, and the support substrate 11 and the support member 18 covered with the resin film are sealed with resin while that space is maintained. In that way, the gap 50 can be provided on the side surface of the support member 18.

As described above, the acoustic wave element 100a may further include the support member 18 between the resin 20 and the side surface of each of the piezoelectric film 14 and the high acoustic velocity member 10, and the gap 50 may be provided between the support member 18 and the resin 20.

In this configuration, a preferred embodiment of the present invention can also be applied to the acoustic wave element 100a having the WLP structure.

Results of Simulation of Stress

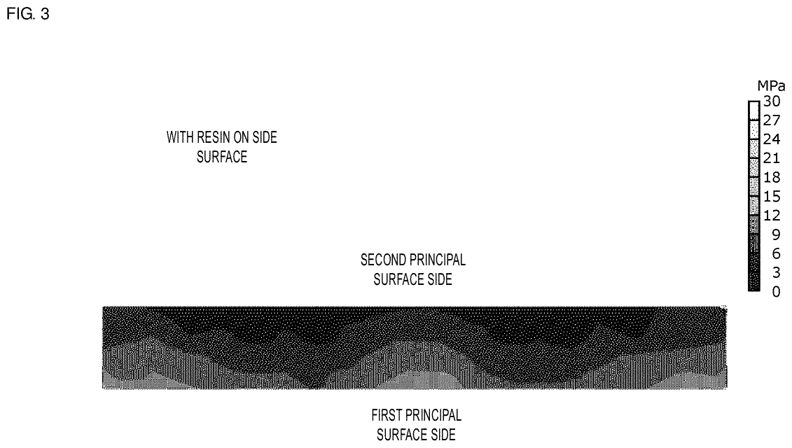

Next, results of a specific simulation of a stress occurring in the piezoelectric film 14 for the case where the gap 50 is provided and a case where the gap 50 is not present on the side surface of the piezoelectric film 14 (or the side surface of the support member 18) are described with reference to FIGS. 3 to 5.

FIG. 3 illustrates a stress occurring in the piezoelectric film 14 when the gap 50 is not provided on the side surface of the piezoelectric film 14. That is, FIG. 3 illustrates a stress occurring in the piezoelectric film 14 in an acoustic wave device in the related art.

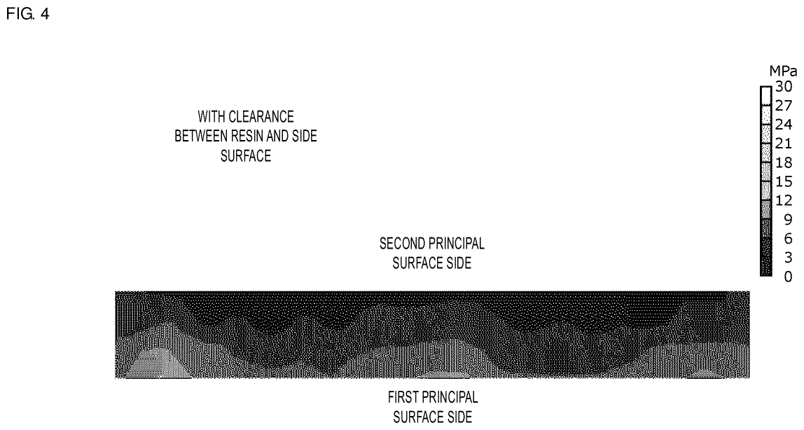

FIG. 4 illustrates a stress occurring in the piezoelectric film 14 when the gap 50 is provided on the side surface of the piezoelectric film 14. That is, FIG. 4 illustrates a stress occurring in the piezoelectric film 14 in the acoustic wave device 1. There is no difference between the stress in the piezoelectric film 14 in the acoustic wave device 1 and that in the acoustic wave device 1a. Therefore, illustration of the results of the simulation for the acoustic wave device 1a is omitted.

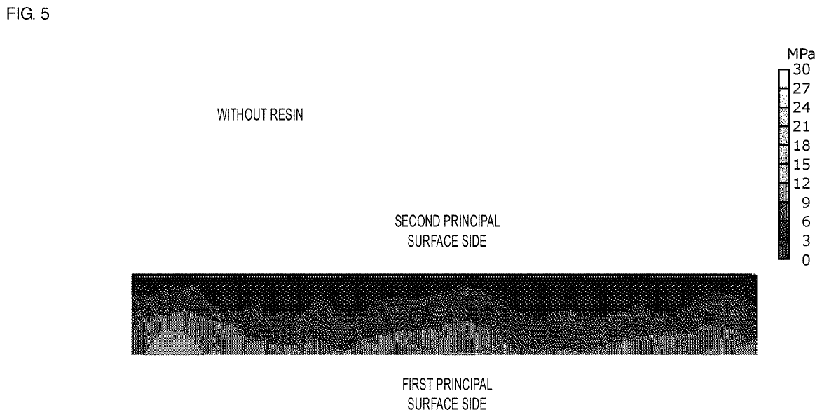

FIG. 5 illustrates a stress occurring in the piezoelectric film 14 when the resin 20 is not provided. That is, FIG. 5 illustrates a stress occurring in the piezoelectric film 14 in a state where the acoustic wave element 100 including the piezoelectric film 14 is not covered with the resin 20 and is exposed. The results for the stress occurring in the piezoelectric film 14 illustrated in FIG. 5 reveal that a large stress is unlikely to occur in the piezoelectric film 14.

As illustrated in FIG. 3, in the case where the gap 50 is not provided on the side surface of the piezoelectric film 14, the stress near the first principal surface of the piezoelectric film 14 (near the IDT electrode 15) is large, and the stress in the piezoelectric film 14 is approximately 27 Mpa at the maximum. As illustrated in FIG. 4, in the case where the gap 50 is provided on the side surface of the piezoelectric film 14, the stress is generally smaller than that in the case where the gap 50 is not provided, and the stress in the piezoelectric film 14 is approximately 24 Mpa at the maximum. The results in the case where the gap 50 is provided on the side surface of the piezoelectric film 14 is similar to that in the case where the acoustic wave element 100 including the piezoelectric film 14 is not covered with the resin 20 illustrated in FIG. 5 (maximum stress: approx. 22.5 MPa). Thus, when the gap 50 is provided on the side surface of the piezoelectric film 14, the stress occurring in the piezoelectric film 14 can be reduced.

For each of the case where the gap 50 is not provided on the side surface of the piezoelectric film 14 and the case where the gap 50 is provided on the side surface of the piezoelectric film 14, the TCF in a specific transmission frequency band and a specific reception frequency band is calculated. In the case where the gap 50 is not provided on the side surface of the piezoelectric film 14, the TCF in the specific transmission frequency band is about 4.6 ppm/° C. and the TCF in the specific reception frequency band is about 3.9 ppm/° C. In the case where the gap 50 is provided on the side surface of the piezoelectric film 14, the TCF in the specific transmission frequency band is about 4.3 ppm/° C. and the TCF in the specific reception frequency band is about 2.6 ppm/° C. Thus, when the gap 50 is provided on the side surface of the piezoelectric film 14, the deterioration of the TCF can be reduced or prevented.

### OTHER PREFERRED EMBODIMENTS

The acoustic wave elements 100 and 100a and the acoustic wave devices 1 and 1a according to preferred embodiments of the present invention are described above. The present invention is not limited to the above-described preferred embodiments. Other preferred embodiments achieved by combining some components in the above-described preferred embodiments, variations obtained by making various modifications conceivable by those skilled in the art to the above-described preferred embodiments within a range that does not depart from the spirit of the present invention, and various kinds of equipment that include the acoustic wave element 100 or 100a or the acoustic wave device 1 or 1a according to preferred embodiments of the present invention are also included in the present invention.

For example, unlike the above-described preferred embodiments, in which the acoustic wave elements 100 and 100a include the low acoustic velocity film 13, the low acoustic velocity film 13 may not be included.

For example, the configuration is not limited to the above-described preferred embodiments, in which the gap 50 is provided between the resin 20 and the side surfaces of the high acoustic velocity film 12 and the low acoustic velocity film 13. For example, the gap 50 may not be provided between the resin 20 and the side surface of the high acoustic velocity film 12. That is, the side surface of the high acoustic velocity film 12 or the support member 18 disposed between the resin 20 and the side surface of the high acoustic velocity film 12 may be in contact with the resin 20. The gap 50 may not be provided between the resin 20 and the side surface of the low acoustic velocity film 13. That is, the side surface of the low acoustic velocity film 13 or the support member 18 disposed between the resin 20 and the side surface of the low acoustic velocity film 13 may be in contact with the resin 20. The bump 30 may preferably be in contact with the gap 50. In that configuration, the piezoelectric film 14 is unlikely to receive an external force from the resin 20 through the bump 30, a large stress is unlikely to occur, and the deterioration of the TCF can be reduced or prevented.

### INDUSTRIAL APPLICABILITY

Preferred embodiments of the present invention can be used in, for example, an acoustic wave device including a multilayer film and sealed with resin.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave element comprising:
a piezoelectric film;
an interdigital transducer electrode on a first principal surface of the piezoelectric film; and
a high acoustic velocity member adjacent to or in a vicinity of a second principal surface of the piezoelectric film; wherein
a surface of the high acoustic velocity member opposite to the piezoelectric film and a side surface of each of the high acoustic velocity member and the piezoelectric film are covered with resin;
at least a portion of the side surface of the high acoustic velocity member is in contact with the resin; and
a gap is provided between the resin and at least a portion of the side surface of the piezoelectric film.

2. The acoustic wave element according to claim 1, wherein
the high acoustic velocity member includes a support substrate and a high acoustic velocity film between the support substrate and the piezoelectric film, an acoustic velocity of a bulk wave propagating in the high acoustic velocity film is higher than an acoustic velocity of an acoustic wave propagating in the piezoelectric film; and
at least a portion of a side surface of the support substrate is in contact with the resin.

3. The acoustic wave element according to claim 2, wherein all of the side surface of the support substrate is in contact with the resin.

4. The acoustic wave element according to claim 1, wherein the gap is provided between the resin and all of the side surface of the piezoelectric film.

5. The acoustic wave element according to claim 1, further comprising:
a low acoustic velocity film between the high acoustic velocity member and the piezoelectric film; wherein
an acoustic velocity of a bulk wave propagating in the low acoustic velocity film is lower than an acoustic velocity of a bulk wave propagating in the piezoelectric film.

6. The acoustic wave element according to claim 1, wherein the gap is in contact with the side surface of the piezoelectric film.

7. The acoustic wave element according to claim 1, further comprising:
a support member between the resin and the side surface of the piezoelectric film; wherein
the gap is provided between the support member and the resin.

8. An acoustic wave device comprising:
the acoustic wave element according to claim 1;
the resin; and
a mounting substrate; wherein
the acoustic wave element is mounted on a first principal surface of the mounting substrate; and
the resin is disposed on the first principal surface of the mounting substrate.

9. The acoustic wave element according to claim 1, wherein the high acoustic velocity film includes at least one of aluminum nitride, aluminum oxide, silicon carbide, silicon nitride, silicon oxynitride, a diamond-like carbon film, or diamond.

10. The acoustic wave element according to claim 5, wherein the low acoustic velocity film includes at least one of silicon dioxide, glass, silicon oxynitride, or tantalum oxide.

11. The acoustic wave element according to claim 1, wherein the piezoelectric film is made of a 50° Y-cut X-propagation lithium tantalate (LiTaO₃) piezoelectric single crystal or piezoelectric ceramic material.

12. The acoustic wave device according to claim 8, wherein
the high acoustic velocity member includes a support substrate and a high acoustic velocity film between the support substrate and the piezoelectric film, an acoustic velocity of a bulk wave propagating in the high acoustic velocity film is higher than an acoustic velocity of an acoustic wave propagating in the piezoelectric film; and
at least a portion of a side surface of the support substrate is in contact with the resin.

13. The acoustic wave device according to claim 12, wherein all of the side surface of the support substrate is in contact with the resin.

14. The acoustic wave device according to claim 8, wherein the gap is provided between the resin and all of the side surface of the piezoelectric film.

15. The acoustic wave device according to claim 8, further comprising:
a low acoustic velocity film between the high acoustic velocity member and the piezoelectric film; wherein
an acoustic velocity of a bulk wave propagating in the low acoustic velocity film is lower than an acoustic velocity of a bulk wave propagating in the piezoelectric film.

16. The acoustic wave device according to claim 8, wherein the gap is in contact with the side surface of the piezoelectric film.

17. The acoustic wave device according to claim 8, further comprising:
a support member between the resin and the side surface of the piezoelectric film; wherein
the gap is provided between the support member and the resin.

18. The acoustic wave device according to claim 8, wherein the high acoustic velocity film includes at least one of aluminum nitride, aluminum oxide, silicon carbide, silicon nitride, silicon oxynitride, a diamond-like carbon film, or diamond.

19. The acoustic wave device according to claim 15, wherein the low acoustic velocity film includes at least one of silicon dioxide, glass, silicon oxynitride, or tantalum oxide.

20. The acoustic wave device according to claim 8, wherein the piezoelectric film is made of a 50° Y-cut X-propagation lithium tantalate (LiTaO₃) piezoelectric single crystal or piezoelectric ceramic material.
